(19) United States
(12) Patent Application Publication
(10) Pub. No.: US 2011/0272025 A1
(43) Pub. Date: Nov. 10, 2011

(54) PHOTOVOLTAIC MODULE

(75) Inventor: Stephen Yau-Sang CHENG, Hong Kong (HK)

(73) Assignee: Du Pont Apollo Limited, Hong Kong (HK)

(21) Appl. No.: 13/099,379

(22) Filed: May 3, 2011

Related U.S. Application Data
(60) Provisional application No. 61/330,985, filed on May 4, 2010.

(51) Int. Cl. H01L 31/0203

(52) U.S. Cl. 136/259

(57) ABSTRACT

Disclosed herein is a photovoltaic module. The photovoltaic module includes a solar cell, a polypropylene layer and a backsheet. The solar cell is capable of converting light into electricity, and has a light-receiving surface and a back surface. The polypropylene layer is disposed above the light-receiving surface of the solar cell. The polypropylene layer has a transparency of greater than 50%. The backsheet is disposed below the back surface of the solar cell.

### RELATED APPLICATIONS

This application claims priority to U.S. Provisional Application Ser. No. 61/330,895, filed May 4, 2010, which is herein incorporated by reference.

### BACKGROUND

1. Field

The present invention relates to a photovoltaic module.

2. Description of Related Art

Photovoltaic cells, also known as solar cells, are devices that convert light into electricity. Solar cells provide a number of advantages when compared to conventional energy sources. For example, solar cells produce electricity without pollution and do not require fossil fuel.

In general, solar modules are disposed outdoors for receiving sunlight. The solar module mechanically supports the solar cells, and protects the solar cells against environmental degradation. The solar module generally comprises a rigid and transparent protective front panel such as glass; and a rear panel or sheet, which is typically called a backsheet. The front panel and backsheet encapsulate the solar cell(s) and provide protection from environmental damage. A goal of the solar industry is to have solar modules with an effective lifetime of decades, e.g. 20 years. Thus, the encapsulation the solar cell(s) is concerned for providing adequate resistance to damage from moisture, temperature, and ultraviolet radiation. Fluorinated material such as TEFLON™ and TEFZEL™ are developed for these purposes, and both fluorinated materials are generally expensive.

However, in certain application, the solar modules do not work in harsh environment. For example, the solar modules that are employed in consumer electronic devices are usually operated indoors, and do not require a long effective lifetime as 20 years. In these applications; the encapsulation of solar cell(s) is required to have a light weight, small size, and commercially acceptable cost. Therefore, there exists in this art a need of an improved solar module, which could satisfy the above-mentioned requirement.

### SUMMARY

A photovoltaic module is provided. The photovoltaic module comprises a solar cell, a polypropylene layer and a backsheet. The solar cell is capable of converting light into electricity, and comprises a light-receiving surface and a back surface. The polypropylene layer is disposed above the light-receiving surface of the solar cell. The polypropylene layer is transparent and has a transparency of greater than 50% in a wavelength range between about 380 nm and about 780 nm. The backsheet is disposed below the back surface of the solar cell. In one embodiment, the polypropylene layer comprises a bi-axial oriented polypropylene or cast polypropylene.

It is to be understood that both the foregoing general description and the following detailed description are by examples, and are intended to provide further explanation of the invention as claimed.

### BRIEF DESCRIPTION OF THE DRAWINGS

The present disclosure can be more fully understood by reading the following detailed description of the embodiments, with reference made to the accompanying drawings as follows:

FIG. 1 is a cross-sectional view schematically illustrating a photovoltaic module according to one embodiment of the present disclosure;

FIG. 2 is a cross-sectional view schematically illustrating a photovoltaic module according to one example of the present disclosure;

FIG. 3 is a cross-sectional view schematically illustrating a photovoltaic module according to another example of the present disclosure;

FIG. 4 is a cross-sectional view illustrating a photovoltaic module according to another embodiment of the present disclosure;

FIG. 5 is a cross-sectional view illustrating a photovoltaic module according to still another embodiment of the present, disclosure;

FIG. 6 is a cross-sectional view illustrating a photovoltaic module according to another embodiment of the present disclosure; and

FIG. 7 is a cross-sectional view illustrating a photovoltaic module according to another embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

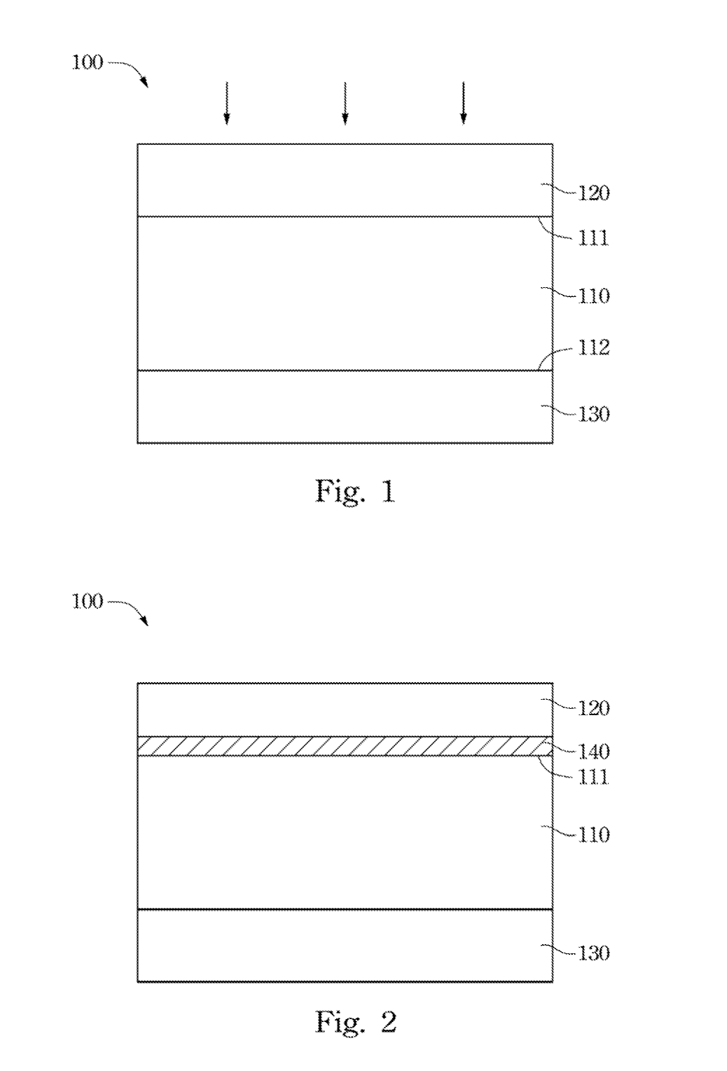

FIG. 1 is a cross-sectional view schematically illustrating a photovoltaic module 100 according to one embodiment of the present disclosure. As depicted in FIG. 1, the photovoltaic module includes a solar cell 110, a polypropylene layer 120 and a backsheet 130.

The solar cell 110 is capable of converting light into electricity, and having a light-receiving surface 111 and a back surface 112. Light may be transmitted to and absorbed by the solar cell 110 through the light-receiving surface 111. When the solar cell 110 absorbs light, electron-hole pairs are generated therein, and then the electron-hole pairs are separated by the electric field established in the solar cell 110, and thus forming the electric current.

There is no specific limitation on the solar cell 110 so long as it may convert light into electricity. The solar cell 110 may be a flexible solar cell formed on a flexible substrate such as polyimide or stainless steel, or a rigid solar cell formed on a rigid substrate such as glass. In one example, the solar cell 110 is a thin film solar cell. In other examples, the solar cell 110 may be a single crystal solar cell or a polycrystalline solar cell, which is formed on a silicon substrate. For increasing the photoelectric conversion efficiency of the solar cell 110, pyramid-like structures or textured structures (not shown) may be formed on the light-receiving surface 111 of the solar cell 110, which is known in the art. In some examples, solar cell 110 includes amorphous silicon and has a p-i-n structure composed of a p-type semiconductor, an intrinsic semiconductor and an n-type semiconductor (not shown). In other examples, the solar cell 110 may include GaAs, CIGS (copper indium gallium (di)selenide), or CdTe.

The polypropylene layer 120 is disposed above the light-receiving surface 111 of the solar cell 110. The polypropylene layer 120 may protect the solar cell 110 from damage, and further prevent mist and moisture from leaking into the solar cell 110. For the propose of the photovoltaic module 100 to absorb light, the polypropylene layer 120 is transparent and has a transparency of greater than 50% in a wavelength range between about 380 nm and about 780 nm. In one example, the polypropylene layer 120 is a layer of bi-axial oriented polypropylene (BOPP). The bi-axial oriented polypropylene has a low permeability of oxygen and moisture, and thus may decrease the amount of oxygen and moisture penetrating into the solar cell 110. Moreover, the BOPP exhibits a high tensile strength, and thereby may provide enough mechanical strength to protect the solar cell 110. In another example, the polypropylene layer 120 is a layer of cast polypropylene (CPP), which has higher tear strength than BOPP, and is suitable for certain application. In some examples, the polypropylene layer 120 may have a multi-layered structure, and may include a layer of BOPP and a layer of CPP. It is to be noted that the polypropylene layer 120 disclosed herein may be applied in both types of flexible and rigid solar cells.

In one example, the polypropylene layer 120 is in contact with the light-receiving surface 111. The polypropylene layer 120 may be laminated onto the solar cell 110 by exerting heat to the polypropylene layer 120 since the polypropylene layer is a thermoplastic material and usually has a melting point of about 190° C. In one example, the thickness of the polypropylene layer 120 is about 1 μm to about 200 μm, more specifically about 50 μm to about 100 μm. In some examples, the polypropylene layer 120 has a textured structure (not shown) formed on the interface between the polypropylene layer 120 and the solar cell 110 or on the outmost surface of the polypropylene layer 120.

In other examples, as depicted in FIG. 2, the photovoltaic module 100 may further include a first heat-sealing layer 140 disposed between the polypropylene layer 120 and the solar cell 110. For instance, the first heat-sealing layer 140 may include an ethylene-propylene copolymer which has a melting point of about 120° C. The first heat-sealing layer 140 may be formed on the polypropylene layer 120 in advance, and then both the polypropylene layer 120 and the first heat-sealing layer 140 may be laminated onto the solar cell 110, with the first heat-sealing layer 140 being situated on the solar cell 110. The first heat-sealing layer 140 may have a lower melting point than polypropylene. As a result, the temperature required to laminate the polypropylene layer 120 may be decreased.

The backsheet 130 is disposed below the back surface 112 of the solar cell 110. The backsheet 130 may be made from ceramic, glass, polymer or metal such as aluminum and stainless steel.

In one embodiment, the backsheet 130 may be made of a thermoplastic polymer and directly adhered onto the back surface 112 of the solar cell 110. In this embodiment, the entire photovoltaic module 100 may further be adhered onto an external article (not shown) by the polymeric backsheet 130. The thickness of the backsheet 130 is about 1 μm to about 200 μm, more specifically about 100 μm to about 200 μm. The material of the backsheet 130 may be the same as or different from the polypropylene layer 120.

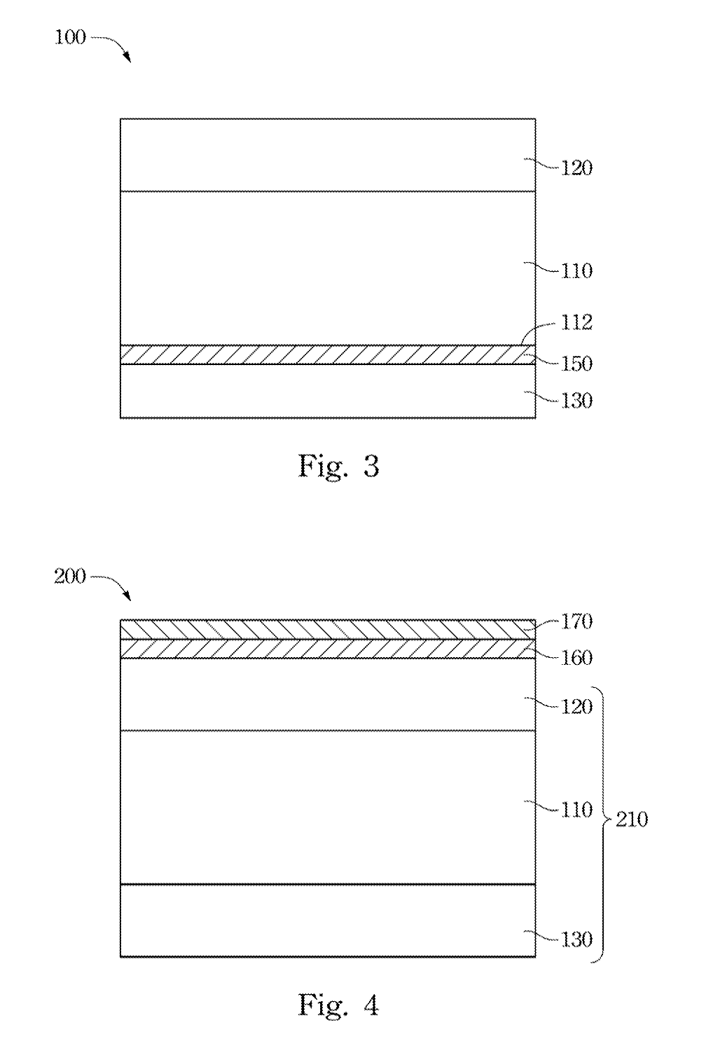

In another embodiment, the backsheet 130 may be made of ceramic, glass, aluminum or stainless steel. In these embodiments, the photovoltaic module may further include a sealing layer 150 disposed between the solar cell 110 and the backsheet 130 as depicted in FIG. 3. The solar cell 110 may be adhered to the backsheet 130 by the sealing layer 150. For example, the sealing layer 150 may be a heat-sealing layer or a pressure sensitive adhesive layer such as an acrylic pressure sensitive polymer or a styrene block copolymer.

FIG. 4 is a cross-sectional view illustrating a photovoltaic module 200 according to another embodiment of the present disclosure. Referring to FIG. 4, the photovoltaic module 200 includes a structure 210, an oxygen barrier layer 160 and a moisture barrier layer 170. The structure 210 is substantially identical to the photovoltaic module 100 depicted in FIG. 1, which includes a solar cell 110, a polypropylene layer 120 and a backsheet 130. The oxygen barrier layer 160 and moisture barrier layer 170 are in sequence disposed on the polypropylene layer 120, with the oxygen barrier layer 160 being in contact with the polypropylene layer 120. In one example, the oxygen barrier layer 160 may be made of ethylene vinyl-alcohol copolymer, and the moisture barrier layer 170 may be a layer of polyvinyldichloride. In some examples, the thickness of the oxygen barrier layer 160 and moisture barrier layer 170 are respectively about 10 μm to about 100 μm and about 10 μm to about 100 μm.

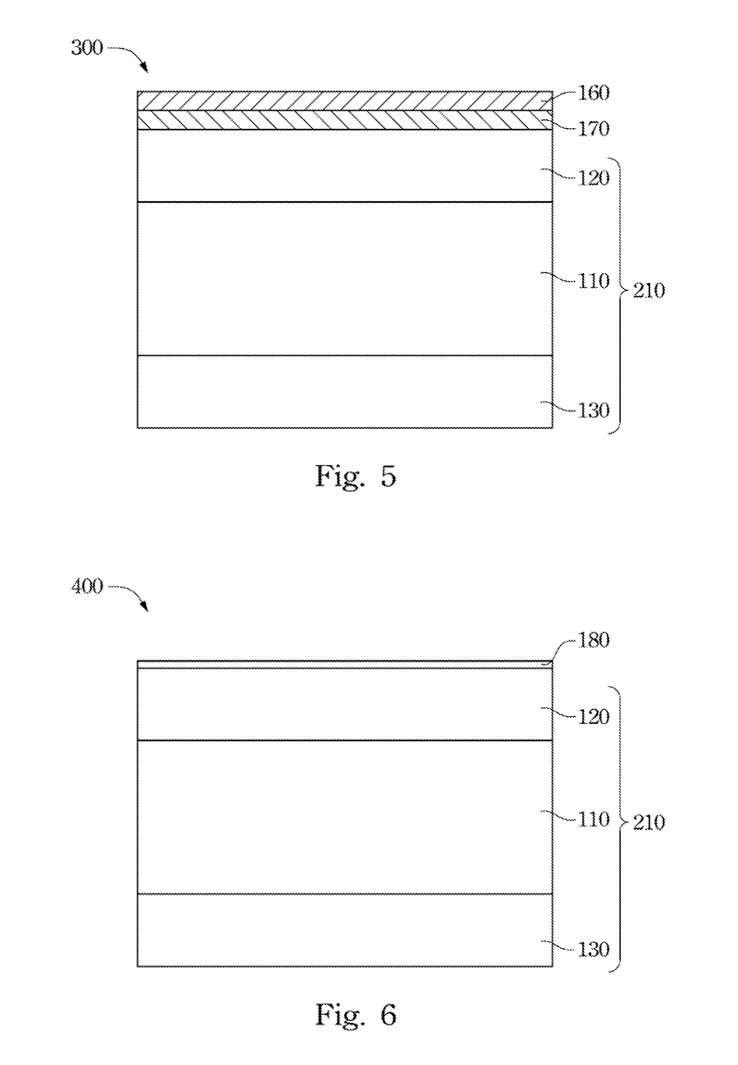

FIG. 5 is a cross-sectional view illustrating a photovoltaic module 300 according to another embodiment of the present disclosure. Referring to FIG. 5, the photovoltaic module 300 includes a moisture barrier layer 170, an oxygen barrier layer 160 and a structure 210. The structure 210 is substantially identical to the solar cell 100 depicted in FIG. 1. In this embodiment, the oxygen barrier layer 160 is disposed at the outmost side of the photovoltaic module 300, and the moisture barrier layer 170 is disposed on the polypropylene layer 120. In this embodiment, the oxygen barrier layer 160 and moisture barrier layer 170 may be same as those described in FIG. 4.

FIG. 6 is a cross-sectional view illustrating a photovoltaic module 400 according to still another embodiment of the present disclosure. The photovoltaic module 400 includes an inorganic layer 180 and a structure 210. The structure 210 is substantially identical to the solar cell 100 depicted in FIG. 1. In this embodiment, the inorganic layer 180 is disposed on the polypropylene layer 120 and is located at the outmost side of the photovoltaic module 400. The inorganic layer 180 may provide a function of light-scattering and resistance to oxygen and moisture as well. In one example, the inorganic layer 180 may include an inorganic oxide such as silicon oxide (SiO₂), zinc oxide, indium oxide, tin oxide or magnesium oxide, and may have a thickness of about 20 nm to 500 nm, for example. In other examples, the inorganic layer 180 may comprise an inorganic nitride such as silicon nitride (Si₃N₄).

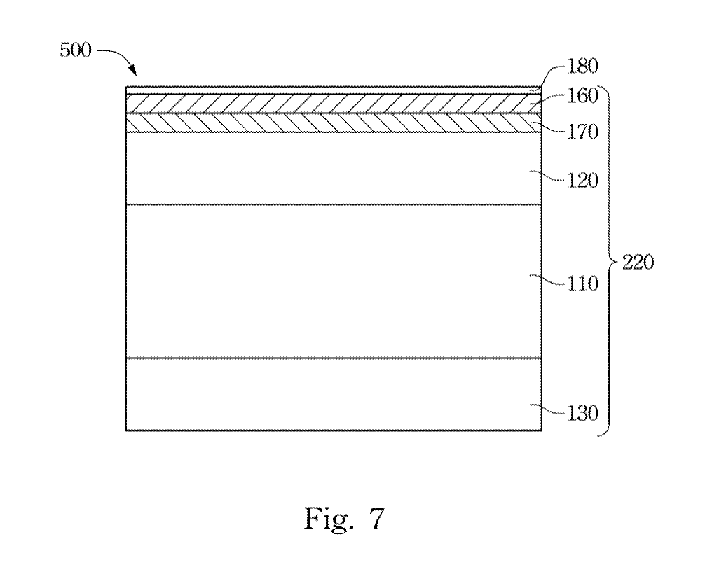

FIG. 7 is a cross-sectional view illustrating a photovoltaic module 500 according to another embodiment of the present disclosure. Referring to FIG. 7, the photovoltaic module 500 includes an inorganic layer 180 and a structure 220. The structure 220 is substantially identical to the photovoltaic module 300 depicted in FIG. 5, which includes a solar cell 110, a polypropylene layer 120, a backsheet 130, an oxygen barrier layer 160 and a moisture barrier layer 170. In this embodiment, the inorganic layer 180 is disposed on the oxygen barrier layer 160 and is arranged at the outmost side of the photovoltaic module 400. The inorganic layer 180 may provide a function of light-scattering, and may facilitate the resistance to oxygen and moisture as well. The inorganic layer 180 may be the same as those described above.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A photovoltaic module comprising:
a solar cell for converting light into electricity, and comprising a light-receiving surface and a back surface;
a polypropylene layer disposed above the light-receiving surface of the solar cell, wherein the polypropylene layer has a transparency of greater than 50% in a wavelength range between about 380 nm and about 780 nm; and
a backsheet disposed below the back surface of the solar cell.

2. The photovoltaic module according to claim 1, wherein the polypropylene layer comprises a layer of bi-axial oriented polypropylene.

3. The photovoltaic module according to claim 1, wherein the polypropylene layer comprises a layer of cast polypropylene.

4. The photovoltaic module according to claim 1, wherein the polypropylene layer is in contact with the light-receiving surface.

5. The photovoltaic module according to claim 1, further comprising a first heat-sealing layer disposed between the polypropylene layer and the solar cell.

6. The photovoltaic module according to claim 5, wherein the heat sealing layer comprises an ethylene-propylene copolymer.

7. The photovoltaic module according to claim 1, further comprising a moisture barrier layer disposed on the polypropylene layer.

8. The photovoltaic module according to claim 7, wherein the moisture barrier layer comprises polyvinyldichloride.

9. The photovoltaic module according to claim 1, further comprising an oxygen barrier layer disposed on the polypropylene layer.

10. The photovoltaic module according to claim 9, wherein the oxygen barrier layer comprises ethylene vinyl-alcohol copolymer.

11. The photovoltaic module according to claim 1, further comprising an inorganic layer disposed onto the polypropylene layer.

12. The photovoltaic module according to claim 11, wherein the inorganic layer comprises an inorganic oxide or inorganic nitride.

13. The photovoltaic module according to claim 12, wherein the inorganic layer comprises silicon oxide, silicon nitride, zinc oxide, indium oxide, tin oxide or magnesium oxide.

14. The photovoltaic module according to claim 1, wherein the backsheet comprises ceramic, glass, polymer, aluminum or stainless steel.

15. The photovoltaic module according to claim 1, wherein the backsheet comprises a thermoplastic polymer adhered to the back surface of the solar cell.

16. The photovoltaic module according to claim 1, further comprising a second heat-sealing layer disposed between the solar cell and the backsheet.

17. The photovoltaic module according to claim 1, further comprising a layer of pressure sensitive adhesive disposed between the solar cell and the backsheet.

18. The photovoltaic module according to claim 1, wherein the polypropylene layer has a thickness of about 1 μm to about 100 μm.

19. The photovoltaic module according to claim 1, wherein the backsheet has a thickness of about 1 μm to about 100 μm.

20. The photovoltaic module according to claim 1, wherein the solar cell comprises amorphous silicon.
